(19) United States
(12) Patent Application Publication
(10) Pub. No.: US 2019/0172986 A1
(43) Pub. Date: Jun. 6, 2019

(54) MANUFACTURING METHOD OF HIGH REFLECTION MIRROR WITH POLYCRYSTALLINE ALUMINUM NITRIDE

(71) Applicant: National Chung-Shan Institute of Science and Technology, Taoyuan City (TW)

(72) Inventors: Chung-Yen Lu, Taoyuan City (TW); Yung-Han Huang, Taoyuan City (TW)

(21) Appl. No.: 16/034,331

(22) Filed: Jul. 12, 2018

(30) Foreign Application Priority Data
Dec. 5, 2017 (TW) 106142482

(51) Int. Cl. H01L 33/60; H01L 33/64; C23C 14/02; C23C 14/06; C23C 14/18; C23C 14/24; C23C 14/35; C23C 14/58; C23C 28/00

(52) U.S. Cl. CPC H01L 33/60; H01L 33/641; C23C 14/022; C23C 14/028; C23C 14/0641; H01L 2933/0075; C23C 14/24; C23C 14/35; C23C 14/5826; C23C 28/32; H01L 2933/0058; C23C 14/18

(57) ABSTRACT

A manufacturing method of a high reflection mirror with polycrystalline aluminum nitride includes (A) providing a polycrystalline aluminum nitride substrate having a polished surface, and utilizing a magnetron sputtering apparatus to react an aluminum target and a plasma formed of nitrogen and argon for forming an aluminum nitride film on the surface of the polycrystalline aluminum nitride substrate, wherein the aluminum nitride film fills into a hole or a gap generated by a lattice defect of the surface of the polycrystalline aluminum nitride substrate; (B) thinning, grinding and polishing the aluminum nitride film for planarizing the polycrystalline aluminum nitride substrate; (C) forming an aluminum coating layer on the aluminum nitride film by a vacuum coating apparatus; (D) forming a sliver coating layer on the aluminum coating layer by another vacuum coating apparatus; and (E) forming a surface-protecting layer on the sliver coating layer.

### CROSS REFERENCE TO RELATED APPLICATION

This application claims the priority benefit of Taiwan Patent Application Serial No. 106142482, filed Dec 5, 2017. The entirety of the above-mentioned patent application is hereby incorporated herein by reference and made a part of this specification.

### BACKGROUND OF THE INVENTION

### 1. Field of the Invention

The present invention relates to a manufacturing method of a reflection coating film with aluminum nitride, and more particularly to a manufacturing method of a high reflection mirror with polycrystalline aluminum nitride.

### 2. Description of the Prior Art

The technique of reflection layer of a LED substrate that can reflect infrared light to visible light has been used widely. In the next developing stage, the technique of reflection mirror for reflecting wide-range light is rapidly developed, which is expected to be applied to reflect light ranged from infrared light to near-ultraviolet. At present, substrate material of the LED reflection film is mostly aluminum oxide and/or silicon-based substrate with low thermal conductance value. However, because the wavelength of near-ultraviolet is short, the generated high heat is easily accumulated in light emitting component. A known research shows that the luminous intensity of the light emitting component will be decreased about 0.05-1% when the temperature is raised with 1° C., which will cause light decay and color shift.

Because aluminum nitride is a ceramic insulator having higher thermal conductive property (a thermal conductance value of polycrystalline aluminum nitride ranges from 70 W·m⁻¹·K⁻¹ to 210 W·m⁻¹·K⁻¹), aluminum nitride material is applied to microelectronics widely. With the improvement of production technique and process equipment, the aluminum nitride ceramic substrate with advantages of both low thermal resistance and voltage durability may be applied to high-power LED illumination industry, so as to enhance performance and reliability of the high-power lighting product.

Nowadays, developing methods of optical film technique mainly include the following items: (1) developing new coating method in aspect of process; (2) applying to wide-range light spectrum in aspect of technique; and (3) modifying the process by designing films and analyzing errors of film thickness through computer assist in aspect of design. The above three items combining with material selecting technique become the whole development framework.

Regarding to the high reflection mirror, the manufacturing method mainly includes: chemical vapor deposition (CVD), molecular beam epitaxy (MBE), plasma assisted chemical vapor deposition (PACVD), laser chemical vapor deposition (LCVD), metal organic chemical vapor deposition (MOCVD), pulsed laser deposition (PLD), magnetron reactive sputtering (MRS) , ion implantation, and so on. Common vapor deposition method of optical film is to heat and evaporate metal or inorganic compound in a vacuum to generate vapor so as to adhered on the substrate and condense into a film. However, the evaporation may make the coating layer weak (or loose) or porous due to a moderate property, and this weak coating layer may be affected by water absorption and therefore the effective refractive index may be changed, which leads to a decrease in performance. Further, the formation rate of the coating layer formed by evaporation is too slow to meet a mass production requirement. In contrast, the magnetron sputtering method is that ions of a target of metal or inorganic compound with high power are released and sputtered on the objective optical component after ions of plasma are accelerated for being in contact with the target of metal or inorganic compound. The magnetron sputtering method increases the kinetic energy of the coating molecules to improve compactness and adhesion of the coating layer, and the magnetron sputtering method has shorter process time to enhance a yield rate effectively.

The technique of reflection film is applied to both of the reflection substrate of LCD backlight module and the reflection substrate of LED light emitting component, in order to increase the luminous intensity of the light source or optical property. The conventional reflection film is common formed on glass, PET, aluminum oxide ceramic, etc., which have low thermal conductive property, or on sapphire, silicon carbide, etc., which have higher price. However, when the above conventional substrates is applied to the high-power light-emitting component, high thermal conductive property, high insulation, smoothness of the surface, processing easily and low cost cannot be satisfied at the same time.

Chinese patent CN 201510567779 provides a manufacturing method of high-reflectivity substrate for LED illumination. This manufacturing method includes following steps: step (1): selecting ceramic, metal or non-metal materials or combination thereof to serve as the base material of the substrate, performing a nano embossing process for preparing an orderly-arranged geometrical structure layer on the surface of the substrate, and evenly distributing graphene powder on the surface of the geometrical structure layer to form a heat dissipation layer; and step (2): performing a film deposition method for depositing optical material onto the surface of the geometrical structure layer to form high-reflectivity layer, wherein the optical material includes at least one of metal or metal oxide. In the above patent, the material of the substrate includes ceramic material including aluminum oxide, aluminum nitride, silicon carbide or zirconium oxide; metal material including iron, steel, copper, aluminum, aluminum-titanium alloy or aluminum-magnesium alloy; non-metal material including polystyrene, polycarbonate, organic glass, ABS plastic, quartz glass or optical glass. Wherein, the ceramic material may closely meet the requirements of high thermal conductive property, high insulation, smoothness of the surface, processing easily and low cost. However, monocrystalline ceramic is expensive to be manufactured, which leads commercialization to being unfavorable; polycrystalline ceramic substrate may have holes and/or gaps generated by lattice defect in the sintering process easily, which leads the substrate to having a worse surface smoothness, so as to affect the reflected light intensity after completing the reflection layer.

The reflective coating material characteristics of the reflection mirror have a close positive correlation with the wavelength of the reflected light. In order to enhance the light intensity reflected by the reflection mirror, the coating structure needs to combine different reflective materials for complementing the reflection efficiency of specific wave band. Chinese patent CN 01122099 invents a high reflection mirror. In CN 01122099, a TiOₓ layer (1≤x≤2) is formed on a base, a silver layer is then formed for serving as a reflection layer, and a protecting layer with Al₂O₃ is formed on the silver layer, such that a reflectivity of light with wavelength ranging from 400 nm to 700 nm is greater than 97%. Chinese patent CN 200620014229 is a utility model related to a novel reflection film, and the film order of the reflection film is: substrate/N1/N2/N1/silver/aluminum, wherein the dielectric layer N1 has a higher refraction index than the dielectric layer N2, the reflection surface is the front surface structure, the substrate is PET film or glass, the material of N1 is TiO, and the reflection film has a high reflectivity of visible light (400 nm-800 nm) ranges from 90% to 95%. The above methods disclose that when using single silver layer to serve as the reflection layer, the light reflectivity in the range only from visible light region to far infrared light region is good, while the reflectivity of near-ultraviolet is bad, which does not meet the requirement of reflecting infrared light, visible light and ultraviolet at the same time. Moreover, Chinese patent CN 201410706122 invents an aluminum-silver multilayer broadband reflection film based on aluminum oxide interlayer including a substrate, a first aluminum oxide film, a first aluminum film, a second aluminum oxide film, a first silver film, a third aluminum oxide film, a second aluminum film, a fourth aluminum oxide film, a second silver film and a fifth aluminum oxide film which are sequentially and closely arranged from bottom to top. The above patent CN 201410706122 utilizes the combination of properties of the aluminum film having low visible light reflectivity and silver film having low ultraviolet reflectivity, such that the result shows the reflection band covers ultraviolet, visible light and infrared light. The above patent forms a stack including nine coating films on the substrate, including two aluminum films and two silver films to serve as reflection layer and five aluminum oxide protecting films, and thus, the process is complicated and costs much time. In addition, the aluminum oxide film with low thermal conductivity is formed as the interlayer, which is disadvantageous to being applied to high-power LED light-emitting component that needs high thermal dissipation. Also, the above patent only discloses the material of the substrate is glass, metal or ceramic, but does not describe the optimization of the smoothness of the surface of the polycrystalline ceramic. However, the smoothness of the surface of the reflection mirror has a high positive correlation with the light reflectivity.

Therefore, the industry needs a manufacturing method of high reflection mirror with aluminum nitride, which can manufacture the reflection mirror in the light-emitting module with thermal dissipation requirement through a simple process, wherein the reflection band of the manufactured reflection mirror covers near-ultraviolet, visible light and infrared light. Accordingly, the reflection mirror in the high-power light-emitting module meeting the industry requirement can be manufactured.

### SUMMARY OF THE INVENTION

Regarding to the aforementioned disadvantages of the prior art, a main purpose of the present invention is to provide a manufacturing method of a high reflection mirror with polycrystalline aluminum nitride. The manufacturing process includes grinding and polishing a surface of a polycrystalline aluminum nitride substrate, sputtering a metal nitride film for filling hole, secondary polishing, manufacturing an aluminum reflection layer, manufacturing a sliver reflection layer and manufacturing a protecting layer, so as to manufacture a high-effective wide frequency band reflection mirror having high thermal conductivity, low cost and high reflective wave-band.

In order to improve an application of the reflection mirror for meeting requirements of high thermal conductivity, high insulation, smoothness of a surface, processing easily and low cost, a manufacturing method of the high reflection mirror with polycrystalline aluminum nitride is developed. The polycrystalline aluminum nitride is configured to be a substrate material. After filling the defects of a surface of the substrate, a reflection stack including aluminum and sliver with specific thicknesses are manufactured, and a protecting layer is formed on a surface of the sliver layer. The present invention may more easily and quickly manufacture a reflection mirror applied to a high-power light-emitting component with a thermal dissipation requirement, and a reflective wave-band of the reflection mirror covers the wave bands of near-ultraviolet, visible light and infrared light.

In order to achieve above purposes, the present invention proposes a solution providing a manufacturing method of a high reflection mirror with polycrystalline aluminum nitride. The manufacturing method includes: (A) providing a polycrystalline aluminum nitride substrate having a polished surface, and utilizing a magnetron sputtering apparatus to react an aluminum target and a plasma formed of nitrogen and argon for forming an aluminum nitride film on the surface of the polycrystalline aluminum nitride substrate, wherein the aluminum nitride film fills into a hole or a gap generated by a lattice defect of the surface of the polycrystalline aluminum nitride substrate; (B) thinning, grinding and polishing the aluminum nitride film for planarizing the polycrystalline aluminum nitride substrate; (C) forming an aluminum coating layer on the aluminum nitride film by a vacuum coating apparatus; (D) forming a sliver coating layer on the aluminum coating layer by another vacuum coating apparatus; and (E) forming a surface-protecting layer on the sliver coating layer.

In the above, the polycrystalline aluminum nitride substrate of the step (A) is formed by a tape casting process or a high temperature sintering cutting molding process, a thermal conductance value of the polycrystalline aluminum nitride substrate having the polished surface of the step (A) is greater than or equal to 170W·m⁻¹·K⁻¹, and a roughness average (Ra) of the polycrystalline aluminum nitride substrate ranges from 20 nm to 30 nm.

In the above, before performing the step (A), the manufacturing method may further include: (1) wiping the polycrystalline semiconductor substrate having the polished surface with a solvent comprising one of acetone, alcohol, and isopropyl alcohol to remove dirt; and (2) removing organic residues and water vapor on the polished surface of the polycrystalline aluminum nitride substrate through an oxygen ion plasma. Wherein, the oxygen ion plasma of step (2) is generated by a reactive ion etching (RIE) process or an induction coupling plasma etching (ICP) process, a gas source of the oxygen ion plasma may be a mixture gas of oxygen and argon, a proportion of nitrogen to argon in the mixture gas is 20%-30%, and the manufacturing time is about 1 minute.

In the above, the magnetron sputtering apparatus of the step (A) is a direct current (DC) sputtering apparatus or a radio frequency (RF) magnetron sputtering apparatus, a thickness of the aluminum nitride film formed by the magnetron sputtering apparatus in step (A) ranges from 5 μm to 15 μm, and the lattice defect of the surface of the polycrystalline aluminum nitride substrate refers to the hole or the gap smaller than 10 μm.

In the above, a method of thinning, grinding and polishing of step (B) is a chemical mechanical polishing (CMP) method or a physical mechanical polishing (PMP) method, and after thinning, grinding and polishing the aluminum nitride film, a thickness of the aluminum nitride film ranges from 5 μm to 10 μm.

In the above, the vacuum coating apparatus of step (C) or step (D) is a vacuum evaporation coating apparatus or a magnetron sputtering coating apparatus. Purities of an aluminum target material and a sliver target material are greater than or equal to 99.5%, and deposition rates of the two metal layers range from 0.5 nm/s to 1 nm/s. A thickness of the formed aluminum coating layer is greater than 100 nm in order to enhance the reflectivity of near-ultraviolet. A thickness of the formed sliver coating layer is greater than 300 nm in order to enhance the reflectivity of infrared light and reflectivity of visible light.

In the above, the surface-protecting layer of step (E) may include one of silicon oxide, magnesium fluoride or aluminum oxide, and a thickness of the surface-protecting layer ranges from 1 μm to 3 μm.

The hole filling method of the polished surface of the polycrystalline aluminum nitride substrate used in the present invention utilizes a reactive magnetron sputtering technique for forming the aluminum nitride film. In the hole filling method, after generating the plasma by controlling a specific proportion of the nitrogen and the argon, the plasma is in contact with the aluminum target to form aluminum nitride, and the aluminum nitride is sputtered to the polished surface of the polycrystalline aluminum nitride substrate to form the aluminum nitride film. This aluminum nitride film may effectively fill the hole defects of the polished surface of the polycrystalline aluminum nitride substrate. Then, the method utilizes a grinding and polishing process to remove the aluminum nitride film on the surface of the substrate but remain the aluminum nitride filled into the hole defects, so as to effectively enhance the smoothness of the surface of the polycrystalline aluminum nitride substrate and decrease light scattering loss caused by the holes or the gaps of the substrate surface. Hereafter, an aluminum coating layer and a sliver coating layer with different thicknesses are manufactured on the polycrystalline aluminum nitride substrate. A result shows that the reflectivity of near-ultraviolet, the reflectivity of infrared light and the reflectivity of visible light of the high reflection mirror with polycrystalline aluminum nitride are raised to be higher than or equal to 90%.

The present invention provides the manufacturing method of the high reflection mirror with polycrystalline aluminum nitride. The characteristics of the manufacturing method includes that the hole defects of the polished surface of the polycrystalline aluminum nitride substrate is first filled by the aluminum nitride film, and then, the grinding and polishing process is performed, so as to enhance the smoothness of the surface and decrease the light scattering loss caused by the hole defects of the surface of the polycrystalline aluminum nitride substrate. Next, the aluminum coating layer and the sliver coating layer with specific thicknesses and specific deposition rates are stacked, such that the high reflective properties (regarding to near-ultraviolet, infrared light and visible light) of two metals are combined to achieve a good reflectivity with wide frequency band. As the result, the manufacture of the high reflection mirror with polycrystalline aluminum nitride having the high thermal conductivity and the high reflectivity with wide frequency band may be completed easily and quickly. The high reflection mirror may be applied to a high-power light-emitting component to enhance the reflectivity of wide frequency band and thermal dissipation.

The above and the following detailed description and drawings are intended to further illustrate the manner, means, and effect of the present invention for achieving predetermined purposes. Other purposes and advantages of the present invention are described in the following detailed description and drawings.

### BRIEF DESCRIPTION OF THE DRAWINGS

The patent or application file contains at least one drawing executed in color. Copies of this patent or patent application publication with color drawing (s) will be provided by the Office upon request and payment of the necessary fee.

FIG. 1 is a flow diagram illustrating a manufacturing method of a high reflection mirror with polycrystalline aluminum nitride according to the present invention;

FIG. 2 is a schematic diagram illustrating a structure formed by a manufacturing method of a high reflection mirror with polycrystalline aluminum nitride according to the present invention;

FIG. 3 is a high magnification optical microscope analysis diagram illustrating a polished surface of a polycrystalline aluminum nitride substrate according to an embodiment of the present invention;

FIG. 4 is an electronic microscope analysis diagram illustrating a cross-section after sputtering an aluminum nitride film on a polycrystalline aluminum nitride substrate according to an embodiment of the present invention;

FIG. 5 is a high magnification optical microscope analysis diagram illustrating a surface after sputtering an aluminum nitride film and secondary polishing according to an embodiment of the present invention;

FIG. 6 is a scanning electronic microscope analysis diagram illustrating a cross-section and a top-view after forming an aluminum coating layer and a sliver coating layer on the polycrystalline aluminum nitride substrate according to an embodiment of the present invention; and

FIG. 7 is measuring diagram illustrating a reflectivity spectrum of a high reflection mirror with polycrystalline aluminum nitride according to an embodiment of the present invention.

### DETAILED DESCRIPTION

Specific embodiments will be detailed in the follow description to explain an implementation of the present invention. Those skilled in the art can easily understand an advantage and an effect of the present invention from contents disclosed in this specification.

The present invention provides a manufacturing method of a high reflection mirror with polycrystalline aluminum nitride. First, the manufacturing method utilizes a process of filling the holes (or gaps) of a surface of a polycrystalline aluminum nitride substrate. A reactive magnetron sputtering technique is used to make ions of a target material with high energy be in contact with the surface of the polycrystalline aluminum nitride substrate, so as to form a compact aluminum nitride for filling the hole defects of the surface of the polycrystalline aluminum nitride substrate. Then, a secondary grinding and polishing process is utilized to remove the surface aluminum nitride film but remain the aluminum nitride filled into the defect, so as to enhance a smoothness of the surface and decrease light scattering loss caused by the holes or the gaps of the surface of the polycrystalline aluminum nitride substrate. Next, an aluminum coating layer and a sliver coating layer with specific thicknesses are manufactured on the polycrystalline aluminum nitride substrate after filling the holes (or the gaps), so as to enhance the reflectivity of near-ultraviolet reflectivity, the reflectivity of infrared light and the reflectivity of visible light of the high reflection mirror with polycrystalline aluminum nitride.

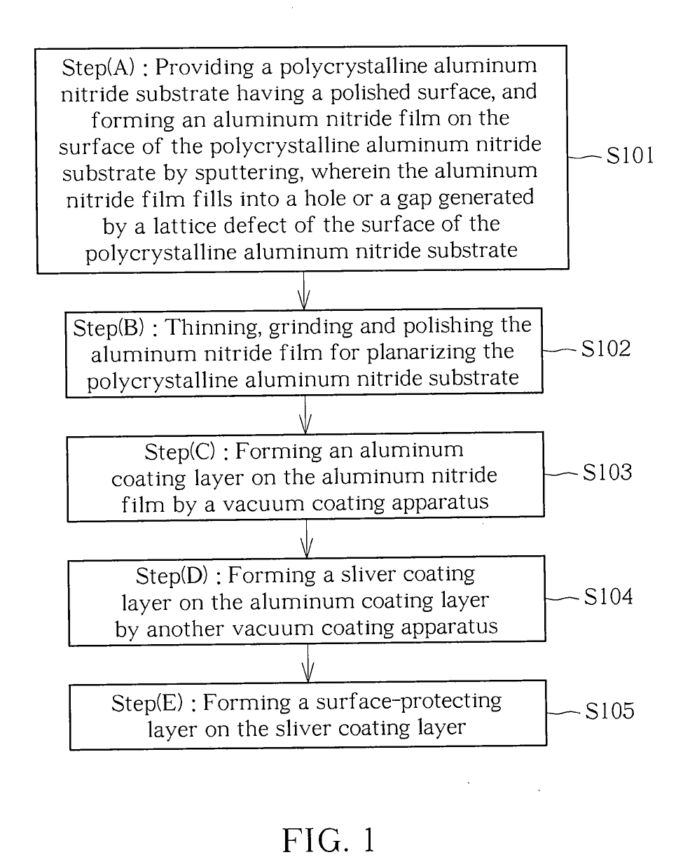

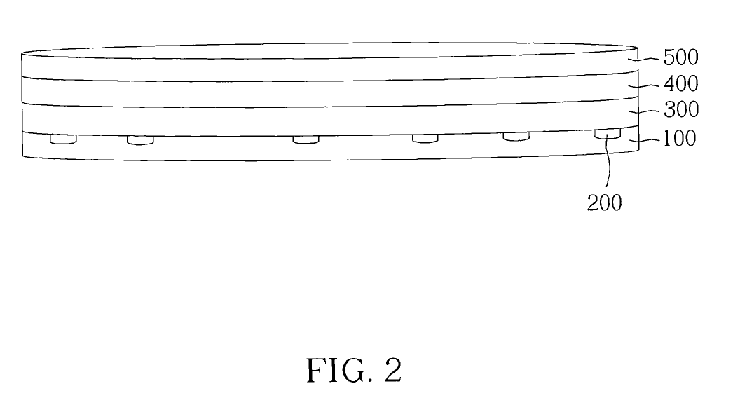

Referring to FIG. 1, FIG. 1 is a flow diagram illustrating a manufacturing method of a high reflection mirror with polycrystalline aluminum nitride according to the present invention. As shown in FIG. 1, the manufacturing method of the high reflection mirror with polycrystalline aluminum nitride includes: (A) providing a polycrystalline aluminum nitride substrate having a polished surface, and utilizing a magnetron sputtering apparatus to react an aluminum target and a plasma formed of nitrogen and argon for forming an aluminum nitride film on the surface of the polycrystalline aluminum nitride substrate, wherein the aluminum nitride film fills into the holes or gaps generated by a lattice defect of the surface of the polycrystalline aluminum nitride substrate (step S101); (B) thinning, grinding and polishing the aluminum nitride film for planarizing the polycrystalline aluminum nitride substrate (step S102); (C) forming an aluminum coating layer on the aluminum nitride film by a vacuum coating apparatus (step S103); (D) forming a sliver coating layer on the aluminum coating layer by a vacuum coating apparatus (step S104); and (E) forming a surface-protecting layer on the sliver coating layer (step S105). Referring to FIG. 2, FIG. 2 is a schematic diagram illustrating a structure formed by a manufacturing method of a high reflection mirror with polycrystalline aluminum nitride according to the present invention. As shown in FIG. 2, a high reflection coating film with aluminum nitride manufactured according to the present invention includes: the polycrystalline aluminum nitride substrate 100, a filled-hole 200 with aluminum nitride film, the high reflection aluminum coating layer 300, the high reflection sliver coating layer 400 and the surface-protecting layer 500.

Wherein, before performing the step (A), the manufacturing method may further include: (1) wiping the polycrystalline semiconductor substrate having the polished surface with a solvent comprising one of acetone, alcohol, and isopropyl alcohol to remove dirt; and (2) removing organic residues and water vapor on the polished surface of the polycrystalline aluminum nitride substrate through an oxygen ion plasma.

### Embodiment 1

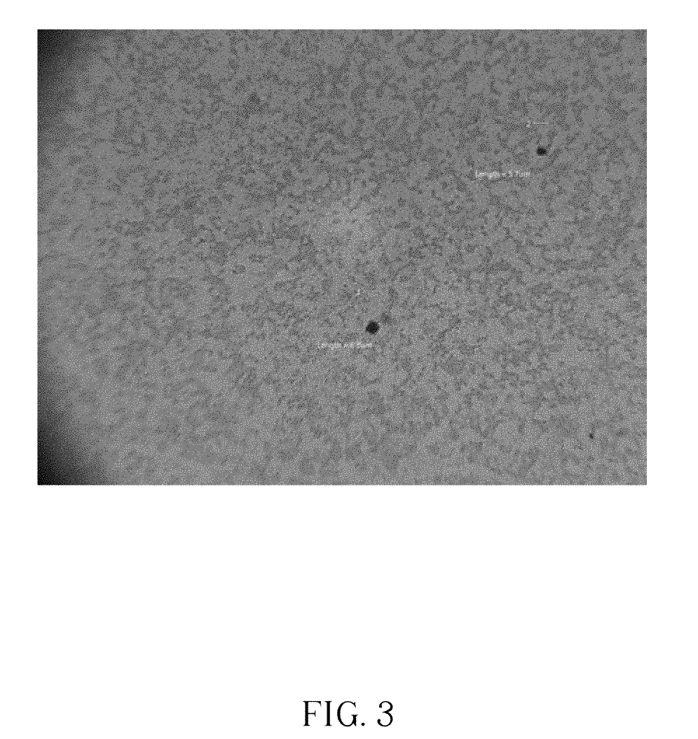

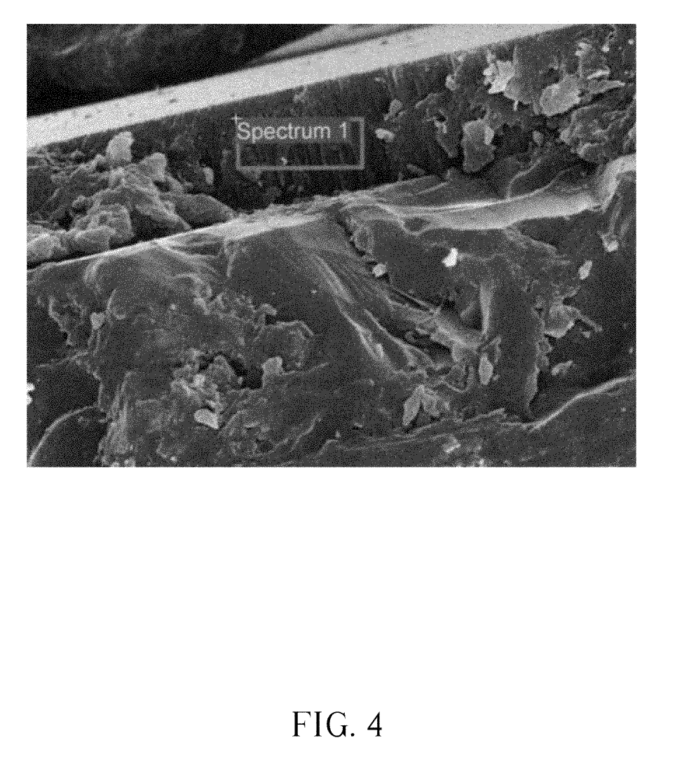

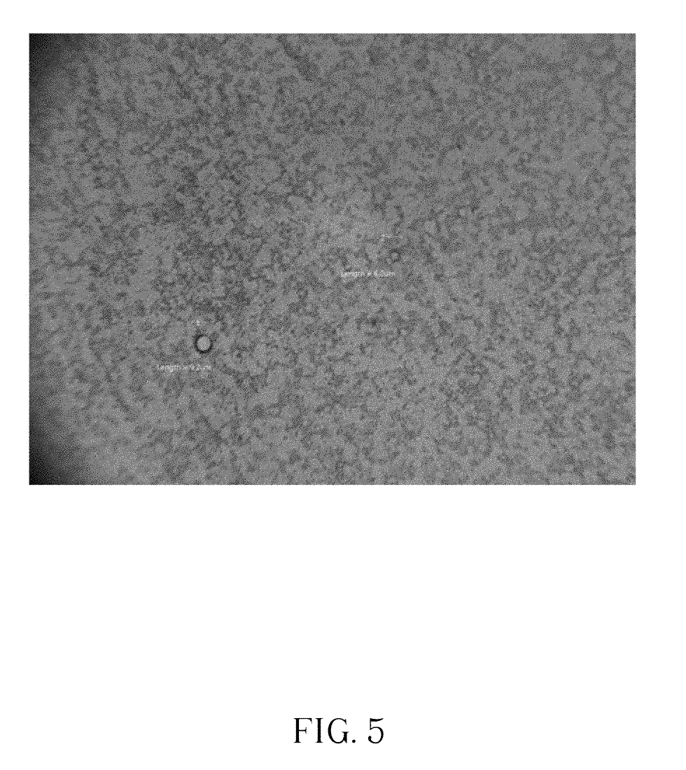

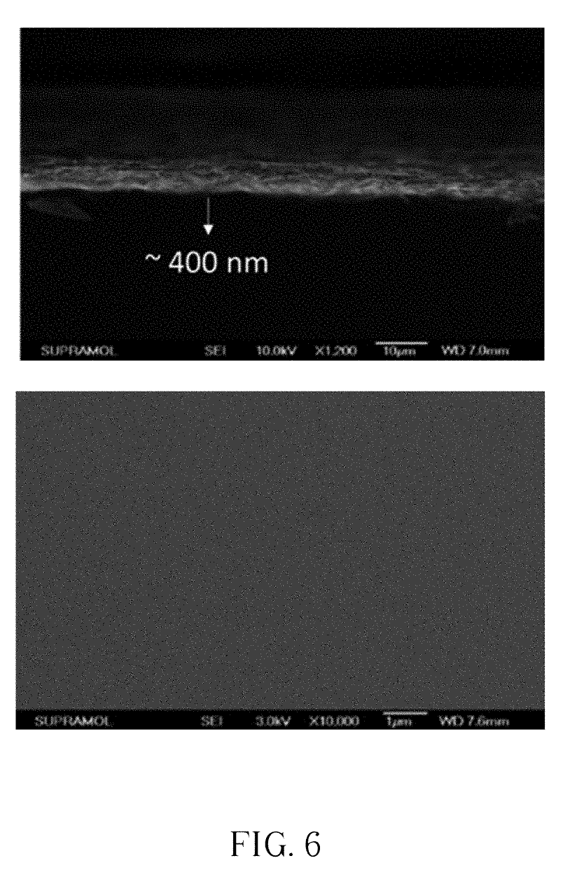

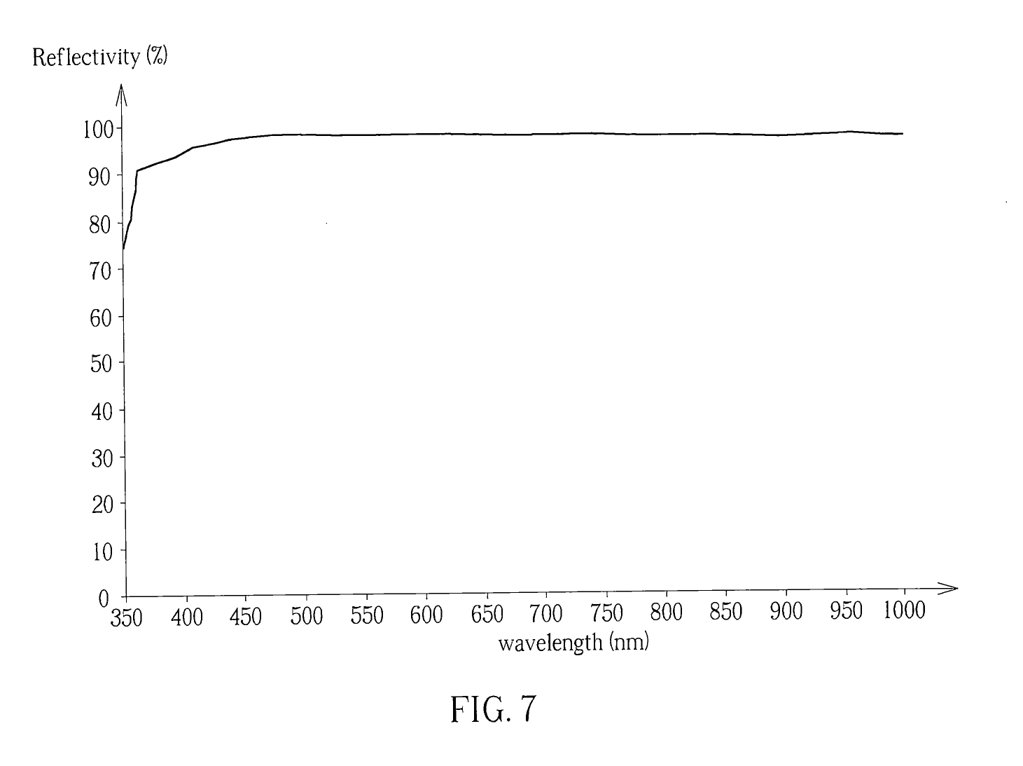

The polycrystalline aluminum nitride substrate having one single polished surface is provided, the thermal conductance value of the polycrystalline aluminum nitride substrate is 179W·m⁻¹·K⁻¹, and the roughness average (Ra) of the polished surface is 27 nm. The polished surface is wiped for cleaning by isopropyl alcohol. Referring to FIG. 3, FIG. 3 is a high magnification optical microscope analysis diagram illustrating a polished surface of a polycrystalline aluminum nitride substrate according to an embodiment of the present invention. As shown in FIG. 3, a size of the hole defect of the polished surface ranges from 5 μm to 10 μm when observing. Then, the polished surface of the polycrystalline aluminum nitride substrate is cleaned by oxygen ion plasma for 1 minute. After removing the organic residues and the water vapor, the polycrystalline aluminum nitride substrate is place into the high vacuum magnetron sputtering apparatus. When the manufactured processing condition of a vacuum level less than 5×10⁻⁸ torr is achieved, by using 1.5KW manufactured processing power, the aluminum target and the plasma formed by the nitrogen of 12 sccm and the argon of 48 sccm are reacted to form aluminum nitride, such that the aluminum nitride is sputtered on the polished surface of the polycrystalline aluminum nitride substrate to form the aluminum nitride film. The process time is 40 minutes. Referring to FIG. 4, FIG. 4 is an electronic microscope analysis diagram illustrating a cross-section after sputtering an aluminum nitride film on a polycrystalline aluminum nitride substrate according to an embodiment of the present invention. As shown in FIG. 4, a thickness of the aluminum nitride film is 9.2 μm by measured. Then, the surface thinning, grinding and polishing processes are performed to the polycrystalline aluminum nitride substrate with the aluminum nitride film filling the lattice defect of the polished surface. In the manufactured processing conditions, first, CMP80 (nanometer scale polishing liquid with main grain size of about 80 nm) is used to perform the polishing process at rotational speed of 30 rpm, temperature of 20° C. and processing pressure of 2 kg/cm² for 20 minutes, and next, CMP20 (nanometer scale polishing liquid with main grain size of about 20 nm) is used to perform the polishing process at rotational speed of 30 rpm, temperature of 20° C. and processing pressure of 2 kg/cm² for 10 minutes, so as to remove the aluminum nitride film on the surface of the substrate and remain the aluminum nitride sputter in the holes. Referring FIG. 5, FIG. 5 is a high magnification optical microscope analysis diagram illustrating a surface after sputtering an aluminum nitride film and secondary polishing according to an embodiment of the present invention. As shown in FIG. 5, by observation, the aluminum nitride film has filled the hole defects of the surface of the polycrystalline aluminum nitride substrate, and a diameter of the hole defect filled by the aluminum nitride film ranges from 5 μm to 10 μm. Thereafter, an aluminum coating layer with a thickness of 100 nm is formed on the polycrystalline aluminum nitride substrate by using a vacuum coating apparatus with a deposition rate of 1 nm/s, so as to enhance the reflectivity of near-ultraviolet. A sliver coating layer with a thickness of 300 nm is formed on the aluminum coating layer by using the vacuum coating apparatus, so as to enhance the reflectivity of infrared light and the reflectivity of visible light. Referring to FIG. 6, FIG. 6 is a scanning electronic microscope analysis diagram illustrating a cross-section and a top-view after forming an aluminum coating layer and a sliver coating layer on the polycrystalline aluminum nitride substrate according to an embodiment of the present invention. As shown in FIG. 6, the reflection coating layers have been coated on this high reflection mirror with polycrystalline aluminum nitride. Then, a magnesium fluoride protecting layer with a thickness of 1 μm is formed on the reflection coating layer by the vacuum coating apparatus. After that, the reflectivity spectrum of the high reflection mirror with polycrystalline aluminum nitride is measured. Referring to FIG. 7, FIG. 7 is measuring diagram illustrating a reflectivity spectrum of a high reflection mirror with polycrystalline aluminum nitride according to an embodiment of the present invention. As shown in the reflectivity spectrum of the high reflection mirror with polycrystalline aluminum nitride, the reflectivity corresponding to the range from near-ultraviolet region to infrared light region (365 nm-1000 nm) is higher than or equal to 90%, wherein the reflectivity of near-ultraviolet with a wavelength of 365 nm is 91.1%.

### Embodiment 2

The polycrystalline aluminum nitride substrate having one single polished surface is provided, the thermal conductance value of the polycrystalline aluminum nitride substrate is 176 μm, and the roughness average (Ra) of the polished surface is 23 nm. The polished surface is wiped for cleaning by isopropyl alcohol. Then, the polished surface of the polycrystalline aluminum nitride substrate is cleaned by oxygen ion plasma for 1 minute. After removing the organic residues and the water vapor, the polycrystalline aluminum nitride substrate is placed into the high vacuum magnetron sputtering apparatus. When the manufactured processing condition of a vacuum level less than 5×10⁻⁸ torr is achieved, by using 1.5KW manufactured processing power, the aluminum target and the plasma formed by the nitrogen of 20 sccm and the argon of 40 sccm are reacted to form aluminum nitride, such that the aluminum nitride is sputtered on the polished surface of the polycrystalline aluminum nitride substrate to form the aluminum nitride film. The process time is 40 minutes. The thickness of the aluminum nitride film is 11.5 μm by measured. Thereafter, the surface thinning, grinding and polishing processes are performed to the polycrystalline aluminum nitride substrate with the aluminum nitride film filling the lattice defect of the polished surface. In the manufactured processing conditions, first, CMP80 (nanometer scale polishing liquid with main grain size of about 80 nm) is used to perform the polishing process at rotational speed of 30 rpm, temperature of 20° C. and processing pressure of 2 kg/cm² for 20 minutes, and next, CMP20 (nanometer scale polishing liquid with main grain size of about 20 nm) is used to performed the polishing process at rotational speed of 30 rpm, temperature of 20° C. and processing pressure of 2 kg/cm² for 10 minutes, so as to remove the aluminum nitride film on the surface of the substrate and remain the aluminum nitride sputter in the holes. Thus, the hole filling process and the secondary polishing process of the aluminum nitride film are completed. By observation, the aluminum nitride film has filled the hole defects of the surface of the polycrystalline aluminum nitride substrate, and the diameter of the hole defects filled by the aluminum nitride film ranges from 5 μm to 10 μm. Thereafter, an aluminum coating layer with a thickness of 100 nm is formed on the polycrystalline aluminum nitride substrate by using the vacuum coating apparatus with a deposition rate of 0.5 nm/s, so as to enhance the reflectivity of near-ultraviolet. A sliver coating layer with a thickness of 300 nm is formed on the aluminum coating layer by using the vacuum coating apparatus, so as to enhance the reflectivity of infrared light and the reflectivity of visible light. Then, a magnesium fluoride protecting layer with a thickness of 1 μm is formed on the reflection coating layer by the vacuum coating apparatus. After that, the reflectivity spectrum of the high reflection mirror with polycrystalline aluminum nitride is measured. The measuring result of the reflectivity spectrum of the high reflection mirror with polycrystalline aluminum nitride shows that the reflectivity corresponding to the range from near-ultraviolet region to infrared light region (365 nm-1000 nm) is higher than or equal to 90%, wherein the reflectivity of near-ultraviolet with a wavelength of 365 nm is 92.4%.

Compared with the conventional high reflection mirror, in the present invention, the holes or the gaps generated by the lattice defect of the polycrystalline ceramic is effectively reduced by the hole filling process and the secondary polishing process of the polycrystalline aluminum nitride film, so as to enhance the smoothness of the substrate and the reflection efficiency. Therefore, the polycrystalline aluminum nitride substrate has better thermal conductivity compared with a glass substrate or a polymer substrate. The polycrystalline aluminum nitride substrate has less surface defect and better reflectivity compared with a polycrystalline ceramic substrate. The polycrystalline aluminum nitride substrate has a cost vantage cost compared with a monocrystalline ceramic substrate. The polycrystalline aluminum nitride substrate has better insulating property compared with a metal substrate. By forming the stack including the aluminum coating layer and the sliver coating layer with specific thicknesses, the high reflection requirements of near-ultraviolet light, visible light and infrared light are achieved simultaneously with less metal reflection layers. As a result, the high reflection mirror with polycrystalline aluminum nitride may achieve the competitive advantages including high thermal conductivity, high insulation, high reflectivity of wide frequency band and low cost, and the high reflection mirror with polycrystalline aluminum nitride can be applied to a high-power light-emitting component with the thermal dissipation requirement, so as to make it be used widely in the future.

The above embodiments are merely to explain the features and effects of the present invention and not to limit the scope of the present invention. Those skilled in the art will readily observe that numerous modifications and alterations of the device and method may be made without departing from the spirit and scope of the invention. Accordingly, the above disclosure should be construed as limited only by the metes and bounds of the appended claims.

What is claimed is:

1. A manufacturing method of a high reflection mirror with polycrystalline aluminum nitride, the manufacturing method comprising following steps:
(A) providing a polycrystalline aluminum nitride substrate having a polished surface, and utilizing a magnetron sputtering apparatus to react an aluminum target and a plasma formed of nitrogen and argon for forming an aluminum nitride film on the surface of the polycrystalline aluminum nitride substrate, wherein the aluminum nitride film fills into a hole or a gap generated by a lattice defect of the surface of the polycrystalline aluminum nitride substrate;
(B) thinning, grinding and polishing the aluminum nitride film for planarizing the polycrystalline aluminum nitride substrate;
(C) forming an aluminum coating layer on the aluminum nitride film by a vacuum coating apparatus;
(D) forming a sliver coating layer on the aluminum coating layer by another vacuum coating apparatus; and
(E) forming a surface-protecting layer on the sliver coating layer.

2. The manufacturing method of the high reflection mirror with polycrystalline aluminum nitride of claim 1, wherein the polycrystalline aluminum nitride substrate of the step (A) is formed by a tape casting process or a high temperature sintering cutting molding process.

3. The manufacturing method of the high reflection mirror with polycrystalline aluminum nitride of claim 1, wherein a thermal conductance value of the polycrystalline aluminum nitride substrate having the polished surface of the step (A) is greater than or equal to 170 W·m⁻¹·K⁻¹, and a roughness average (Ra) of the polycrystalline aluminum nitride substrate ranges from 20 nm to 30 nm.

4. The manufacturing method of the high reflection mirror with polycrystalline aluminum nitride of claim 1, wherein before performing the step (A), the manufacturing method further comprises:
(1) wiping the polycrystalline semiconductor substrate having the polished surface with a solvent comprising one of acetone, alcohol, and isopropyl alcohol to remove dirt;
(2) removing organic residues and water vapor on the polished surface of the polycrystalline aluminum nitride substrate through an oxygen ion plasma.

5. The manufacturing method of the high reflection mirror with polycrystalline aluminum nitride of claim 4, wherein the oxygen ion plasma of step (2) is generated by a reactive ion etching (RIE) process or an induction coupling plasma etching (ICP) process.

6. The manufacturing method of the high reflection mirror with polycrystalline aluminum nitride of claim 4, wherein a gas source of the oxygen ion plasma of step (2) is a mixture gas of oxygen and argon.

7. The manufacturing method of the high reflection mirror with polycrystalline aluminum nitride of claim 1, wherein the magnetron sputtering apparatus of the step (A) is a direct current (DC) sputtering apparatus or a radio frequency (RF) magnetron sputtering apparatus.

8. The manufacturing method of the high reflection mirror with polycrystalline aluminum nitride of claim 1, wherein a thickness of the aluminum nitride film of step (A) ranges from 5 μm to 15 μm.

9. The manufacturing method of the high reflection mirror with polycrystalline aluminum nitride of claim 1, wherein a method of thinning, grinding and polishing of step (B) is a chemical mechanical polishing (CMP) method or a physical mechanical polishing (PMP) method.

10. The manufacturing method of the high reflection mirror with polycrystalline aluminum nitride of claim 1, wherein after thinning, grinding and polishing the aluminum nitride film of step (B), a thickness of the aluminum nitride film ranges from 5 μm to 10 μm.

11. The manufacturing method of the high reflection mirror with polycrystalline aluminum nitride of claim 1, wherein the vacuum coating apparatus of step (C) or step (D) is a vacuum evaporation coating apparatus or a magnetron sputtering coating apparatus.

12. The manufacturing method of the high reflection mirror with polycrystalline aluminum nitride of claim 1, wherein a thickness of the aluminum coating layer of step (C) is greater than 100 nm.

13. The manufacturing method of the high reflection mirror with polycrystalline aluminum nitride of claim 1, wherein a thickness of the sliver coating layer of step (D) is greater than 300 nm.

14. The manufacturing method of the high reflection mirror with polycrystalline aluminum nitride of claim 1, wherein the surface-protecting layer of step (E) comprises one of silicon oxide, magnesium fluoride or aluminum oxide.

15. The manufacturing method of the high reflection mirror with polycrystalline aluminum nitride of claim 1, wherein a thickness of the surface-protecting layer of step (E) ranges from 1 μm to 3 μm.
